(19) United States
(12) Patent Application Publication
(10) Pub. No.: US 2026/0018225 A1
(43) Pub. Date: Jan. 15, 2026

(54) DEFECTIVE WORD LINE SCAN

(71) Applicant: Micron Technology, Inc., Boise, ID (US)

(72) Inventors: Dongxiang Liao, Cupertino, CA (US); Lei Lin, Fremont, CA (US)

(21) Appl. No.: 19/259,366

(22) Filed: Jul. 3, 2025

Related U.S. Application Data
(60) Provisional application No. 63/669,970, filed on Jul. 11, 2024.

(51) Int. Cl. G11C 29/02; G11C 16/34; G11C 29/52

(52) U.S. Cl. CPC G11C 29/022; G11C 16/349; G11C 29/52

(57) ABSTRACT

Systems and methods for providing a memory sub-system controller that selectively performs extrinsic defect scan operations on certain word line groups of a memory sub-system are described. The controller performs an extrinsic defect scan operation on a set of predetermined portions of a set of memory components. The controller, in response to performing the extrinsic defect scan operation, stores a map that identifies a subset of the predetermined portions of the set of memory components having a reliability value that fails to satisfy a reliability criterion. The controller, in response to storing the map, performs one or more subsequent extrinsic defect scan operations on the identified subset of the predetermined portions of the set of memory components having the reliability value that fails to satisfy the reliability criterion.

### PRIORITY APPLICATION

This application claims the benefit of priority to U.S. Provisional Application Ser. No. 63/669,970, filed Jul. 11, 2024, which is incorporated herein by reference in its entirety.

### TECHNICAL FIELD

This disclosure relates generally to memory sub-systems and, more specifically, to providing adaptive media management for memory components, such as memory dies.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data on the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 is a block diagram illustrating an example computing environment including a memory sub-system, in accordance with some examples.

FIG. 2 is a block diagram of an example media operations manager, in accordance with some examples.

FIGS. 3 and 4 are block diagrams of examples of extrinsic defect scan operations, in accordance with some examples.

FIG. 5 is a flow diagram of an example method to selectively perform an RDCL scan on memory components, in accordance with some examples.

FIG. 6 is a block diagram illustrating a diagrammatic representation of a machine in the form of a computer system within which a set of instructions can be executed for causing the machine to perform any one or more of the methodologies discussed herein, in accordance with some examples.

### DETAILED DESCRIPTION

The present disclosure configures a system component, such as a memory sub-system controller, to perform selective extrinsic defect scan operations (e.g., read disturb induced charge loss (RDCL) scans) on a word line (WL), WL group (WLG), component, memory die, and/or sub-block basis and based on a defect or reliability map associated with a memory sub-system. The memory sub-system controller can, during a beginning of life (BOL) period of the memory sub-system, perform an aggressive extrinsic defect scan operation on mandatory (e.g., predetermined) portions (e.g., WL, WLG, memory dies, and so forth) of a set of memory components. The controller can use a result of the aggressive extrinsic defect scan operation to build or generate a table that identifies a subset of the mandatory portions that have a reliability value that fails to satisfy a reliability criterion (e.g., are associated with a read bit error rate (RBER) that is greater than an adjusted predetermined RBER). Then, during an end of life (EOL) period of the memory sub-system, the controller can restrict performing the extrinsic defect scan operation to only those portions that are identified in the table. This ensures that performance of the memory system remains optimal, such as by restricting the number of portions for which an extrinsic defect scan operation is performed to only those portions known to be defective or that have poor reliability. This improves the overall efficiency of operating the memory sub-system.

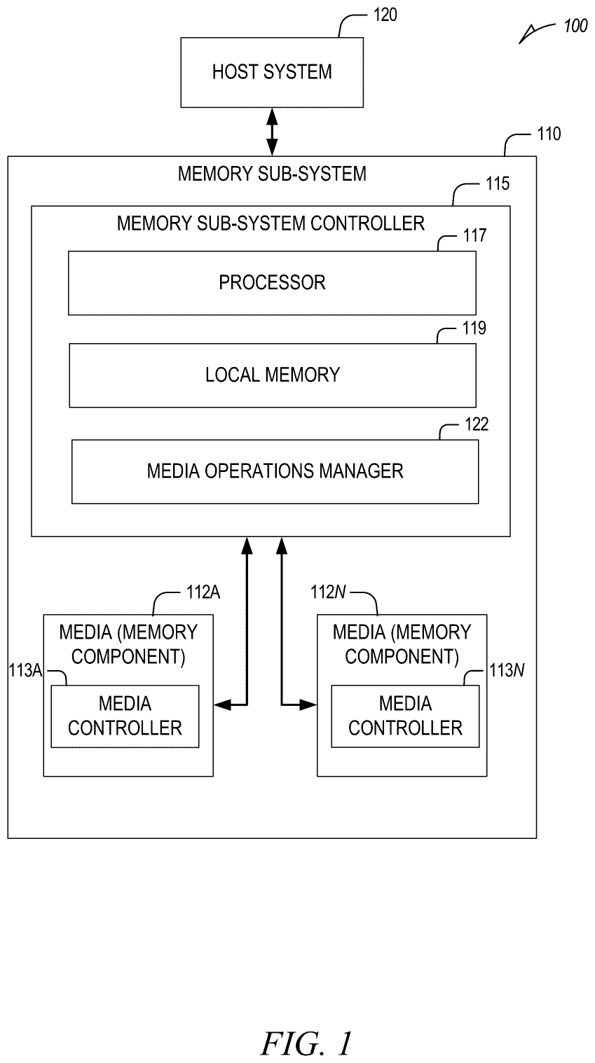

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data”.

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written, for example as initiated by the firmware, is hereinafter referred to as “garbage collection data”. “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package.

There are challenges in efficiently managing or performing media management operations on typical memory devices. Specifically, certain memory devices, such as NAND flash devices, include large die-by-die reliability (RWB) variation. As the technology for such memory devices continues to be scaled down, this die-by-die reliability variation becomes more pronounced and problematic in performing memory management. Current memory systems (e.g., SSD drive or die package systems) associate all of the memory devices or memory dies in the memory system with a certain reliability specification. Such reliability specifications can be set based on a RBER of different portions of the memory sub-system. In some cases, each block of each memory device is associated with a reliability grade or specification which is used to determine whether the block is a good block or a bad block. Good blocks are those that have reliability grades (e.g., RBER values) above a reliability threshold (e.g., above an RBER threshold) and bad blocks are blocks that have reliability grades below a reliability threshold. The reliability grades can be set at manufacture or during operation of the memory devices, such as by measuring the data retention and/or error rate associated with particular blocks, WLs, WLGs, and/or sub-blocks (SBs).

Some media management operations include RDCL scan operations. The RDCL scan operations in NAND flash memory are important maintenance processes aimed at preserving data integrity. The RDCL operations begin with the memory controller monitoring the number of read operations for each memory block, WL, WLG, or other suitable portion. Once the portion reaches a predefined threshold of read operations, indicating a higher risk of data corruption due to read disturbs, the portion is flagged for further action. The memory controller then checks the charge levels in the cells of these portions to detect any discrepancies or charge loss. If issues are found, the original data is rewritten to the cells, restoring the correct charge levels and correcting errors (e.g., the data is refreshed). In some cases, the RDCL operations are performed on certain predetermined or mandatory WLs or portions. As memory sub-systems grow in size and greater performance constraints are imposed, a wider number of portions or WLs need to be included as part of the mandatory WLs that are monitored during the RDCL scan operations. However, increasing the number of portions or WLs scanned as part of the RDCL scan operations can impact performance and efficiency, which can cause the memory sub-system to fail to meet certain performance needs. Also, arbitrarily skipping certain portions to reduce the number of portions scanned as part of the RDCL scan operations can result in inadvertently missing errors, which can result in poor memory performance. This creates significant inefficiencies and wastes resources.

The present disclosure addresses the above and other deficiencies by providing a memory controller that can selectively and intelligently perform extrinsic defect scan operations (e.g., RDCL scan operations) on certain portions of the memory components (e.g., certain WL, WLGs, memory dies, and so forth) that are known to have defects or poor reliability. Specifically, the memory sub-system controller can perform an initial set of extrinsic defect scan operations on mandatory (e.g., predetermined) portions (e.g., WL, WLG, memory dies, and so forth) of a set of memory components and use a result of the initial extrinsic defect scan operations to build or generate a table that identifies a subset of the mandatory portions that have a reliability value that fails to satisfy a reliability criterion. The controller can then restrict performing subsequent extrinsic defect scan operations to only those portions that are identified in the table. This ensures that performance of the memory system remains optimal, such as by restricting the number of portions for which an extrinsic defect scan operation is performed to only those portions known to be defective or that have poor reliability. This improves the overall efficiency of operating the memory sub-system.

In some cases, the memory controller performs an extrinsic defect scan operation on a set of predetermined portions of the set of memory components. The memory controller, in response to performing the extrinsic defect scan operation, stores a map that identifies a subset of the predetermined portions of the set of memory components having a reliability value that fails to satisfy a reliability criterion. The memory controller, in response to storing the map, performs one or more subsequent extrinsic defect scan operations on the identified subset of the predetermined portions of the set of memory components having the reliability value that fails to satisfy the reliability criterion. The memory sub-system can include a three-dimensional (3D) NAND memory.

The memory controller can determine that a program erase count (PEC) or number of read/write operations is associated with the set of memory components corresponds to a beginning of life (BOL) period. The memory controller, in response to determining that the PEC or number of read/write operations is associated with the set of memory components corresponding to the BOL period, performs the extrinsic defect scan operation on the set of predetermined portions of the set of memory components. In some cases, the memory controller obtains a predetermined reliability threshold associated with the extrinsic defect scan operation, and during the BOL period, modifies the predetermined reliability threshold to increase sensitivity of the reliability criterion. The predetermined reliability threshold can represent a predetermined RBER value. The reliability value can include a RBER of the subset of the predetermined portions of the set of memory components. In such cases, the memory controller can reduce the predetermined RBER value of the predetermined reliability threshold to increase sensitivity of the reliability criterion.

The memory controller can measure the RBER value of each set of predetermined portions of the set of memory components responsive to performing the extrinsic defect scan operation during the BOL period. The memory controller determines that the RBER value of an individual portion of the set of predetermined portions transgresses the reduced predetermined RBER value. The memory controller, in response to determining that the RBER value of the individual portion of the set of predetermined portions transgresses the reduced predetermined RBER value, adds the individual portion to the map of the subset of the predetermined portions of the set of memory components having the reliability value that fails to satisfy the reliability criterion.

In some examples, the memory controller triggers refresh of data stored in one or more portions of the subset of the predetermined portions of the set of memory components in response to determining that RBER values associated with the one or more portions of the subset of the predetermined portions transgress the predetermined RBER value. In some cases, the memory controller continues to perform the extrinsic defect scan operation on the set of predetermined portions of the set of memory components until the PEC or number of read/write operations associated with the set of memory components corresponds to an EOL period.

The memory controller can determine that the set of memory components corresponds to the EOL period and, in response, perform the one or more subsequent extrinsic defect scan operations on the identified subset of the predetermined portions of the set of memory components having the reliability value that fails to satisfy the reliability criterion. In some cases, the identified subset excludes one or more portions that are in the predetermined portions of the set of memory components. The extrinsic defect scan operation can be performed on a first number of portions of the set of memory components during the BOL period, and the one or more subsequent extrinsic defect scan operations can be performed on a second number of portions of the set of memory components during the EOL period. The second number of portions can be smaller than the first number of portions.

In some examples, the set of portions includes at least one of a set of WLs, WLGs, and/or set of memory dies. In some cases, the extrinsic defect scan operation and the one or more subsequent extrinsic defect scan operations are triggered periodically. The extrinsic defect scan operation and the one or more subsequent extrinsic defect scan operations can be triggered in response to determining that a number of read operations performed on the memory sub-system within a predetermined interval transgresses a threshold value.

Though various examples are described herein as being implemented with respect to a memory sub-system (e.g., a controller of the memory sub-system), some or all of the portions of an embodiment can be implemented with respect to a host system, such as a software application or an operating system of the host system.

FIG. 1 illustrates an example computing environment 100 including a memory sub-system 110, in accordance with some examples. The memory sub-system 110 can include media, such as memory components 112A to 112N (also hereinafter referred to as “memory devices”). The memory components 112A to 112N can be volatile memory devices, non-volatile memory devices, or a combination of such. The memory components 112A to 112N can be implemented by individual dies, such that a first memory component 112A can be implemented by a first memory die (or a first collection of memory dies) and a second memory component 112N can be implemented by a second memory die (or a second collection of memory dies). Each memory die can include a plurality of planes in which data can be stored or programmed.

In some examples, the first memory component 112A, including one or more portions (e.g., one or more WLs, one or more WLGs, one or more blocks, one or more memory dies, and/or one or more pages) or group of memory components including the first memory component 112A, can be associated with a first reliability (capability) grade, value, measure, or lifetime PEC. The terms “reliability grade,” “value” and “measure” are used interchangeably throughout and can have the same meaning. The second memory component 112N (e.g., one or more WLs, one or more WLGs, one or more blocks, one or more memory dies, and/or one or more pages) or group of memory components, including the second memory component 112N, can be associated with a second reliability (capability) grade, value, measure, or lifetime PEC. In some examples, each memory component 112A to 112N can store respective configuration data that specifies the respective reliability grade and lifetime PEC and current PEC. In some examples, a memory or register can be associated with all of the memory components 112A to 112N and can store a table that maps different groups, portions, bins or sets of the memory components 112A to 112N to respective reliability grades, lifetime PEC values, and/or current PEC values.

In some examples, a memory or register can be associated with all of the memory components 112A to 112N and can store a table or map that maps different WL, WLGs, SBs, memory dies, and/or portions of the memory components 112A to 112N to reliability values that transgress a threshold. Namely, the memory or register can store a map that lists each WL, WLG, and/or SB that has been determined during manufacture to be defective (e.g., have a reliability value that fails to transgress a reliability threshold). In some cases, the table or map can be generated based on a distribution of errors or defects associated with a certain wafer, die sort, lot, or batch. A determination can be made that the memory sub-system 110 is part of a particular wafer, die sort, lot or batch and can then be loaded with the configuration data that includes the table or map associated with another memory sub-system 110 that is part of the same wafer, die sort, lot, or batch. In some cases, the list of portions that are in the table are referred to as mandatory WLs or mandatory portions (e.g., predetermined portions of the set of memory components 112A to 112N). These mandatory portions can be included in an extrinsic defect scan operation (e.g., an RDCL scan operation) to condition performing refresh operations if the RBER of the data read from the portions transgresses a maximum or predefined RBER threshold.

In some examples, the memory sub-system 110 is a storage system. A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to a memory system. The memory system can include one or more memory sub-systems 110. In some examples, the host system 120 is coupled to different types of memory sub-systems 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL), a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory components 112A to 112N when the memory sub-system 110 is coupled with the host system 120 by the PCIe or CXL interface. The physical host interface can provide an interface for passing control, address, data, and other signals between the memory sub-system 110 and the host system 120.

The memory components 112A to 112N can include any combination of the different types of non-volatile memory components and/or volatile memory components. An example of non-volatile memory components includes a negative- and (NAND)-type flash memory and/or a 3D NAND flash memory. Each of the memory components 112A to 112N can include one or more arrays of memory cells such as single-level cells (SLCs) or multi-level cells (MLCs) (e.g., TLCs or QLCs). In some examples, a particular memory component 112 can include both an SLC portion and an MLC portion of memory cells. Each of the memory cells can store one or more bits of data (e.g., blocks) used by the host system 120. Although non-volatile memory components such as NAND-type flash memory are described, the memory components 112A to 112N can be based on any other type of memory, such as a volatile memory. In some examples, the memory components 112A to 112N can be, but are not limited to, random access memory (RAM), read-only memory (ROM), dynamic random access memory (DRAM), synchronous dynamic random access memory (SDRAM), phase change memory (PCM), magnetoresistive random access memory (MRAM), negative-or (NOR) flash memory, electrically erasable programmable read-only memory (EEPROM), and a cross-point array of non-volatile memory cells.

A cross-point array of non-volatile memory cells can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. Furthermore, the memory cells of the memory components 112A to 112N can be grouped as memory pages or blocks that can refer to a unit of the memory component 112 used to store data. For example, a single first row that spans a first set of the pages or blocks of the memory components 112A to 112N can correspond to or be grouped as a first block stripe and a single second row that spans a second set of the pages or blocks of the memory components 112A to 112N can correspond to or be grouped as a second block stripe.

The memory sub-system controller 115 can communicate with the memory components 112A to 112N to perform memory operations such as reading data, writing data, or erasing data at the memory components 112A to 112N and other such operations. The memory sub-system controller 115 can communicate with the memory components 112A to 112N to perform various memory management operations, such as different scan rates, different scan frequencies, different wear leveling, different read disturb management, garbage collection operations, different near miss ECC operations, RDCL scan operations, and/or different dynamic data refresh operations.

The memory sub-system controller 115 can include hardware such as one or more integrated circuits and/or discrete components, a buffer memory, or a combination thereof. The memory sub-system controller 115 can be a microcontroller, special-purpose logic circuitry (e.g., a field programmable gate array (FPGA), an application specific integrated circuit (ASIC), etc.), or another suitable processor. The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. In some embodiments, the local memory 119 can include memory registers storing memory pointers, fetched data, and so forth. The local memory 119 can also include read-only memory (ROM) for storing microcode. While the example memory sub-system 110 in FIG. 1 has been illustrated as including the memory sub-system controller 115, in another example of the present disclosure, a memory sub-system 110 may not include a memory sub-system controller 115, and can instead rely upon external control (e.g., provided by an external host, or by a processor 117 or controller separate from the memory sub-system 110).

In general, the memory sub-system controller 115 can receive commands or operations from the host system 120 and can convert the commands or operations into instructions or appropriate commands to achieve the desired access to the memory components 112A to 112N. In some examples, the commands or operations received from the host system 120 can specify configuration data for the memory components 112N to 112N. The configuration data can describe the lifetime PEC values and/or reliability grades associated with different groups of the memory components 112N to 112N and/or different WLs, WLGs, and/or blocks within each of the memory components 112N to 112N. The configuration data can include a table that lists WLs, WLGs, and/or SBs that are known to be defective to be included as part of the mandatory WLs, WLGs, and/or SBs to include in an RDCL scan or other extrinsic defect scan operation.

The memory sub-system controller 115 can be responsible for other memory management operations, such as wear leveling operations, garbage collection operations, error detection and error-correcting code (ECC) operations, encryption operations, caching operations, read scan, and address translations. The memory sub-system controller 115 can further include host interface circuitry to communicate with the host system 120 via the physical host interface. The host interface circuitry can convert the commands received from the host system 120 into command instructions to access the memory components 112A to 112N as well as convert responses associated with the memory components 112A to 112N into information for the host system 120.

The memory sub-system 110 can also include additional circuitry or components that are not illustrated. In some embodiments, the memory sub-system 110 can include a cache or buffer (e.g., DRAM or other temporary storage location or device) and address circuitry (e.g., a row decoder and a column decoder) that can receive an address from the memory sub-system controller 115 and decode the address to access the memory components 112A to 112N.

The memory devices can be raw memory devices (e.g., NAND), which are managed externally, for example, by an external controller (e.g., memory sub-system controller 115). The memory devices can be managed memory devices (e.g., managed NAND), which is a raw memory device combined with a local embedded controller (e.g., local media controllers) for memory management within the same memory device package. Any one of the memory components 112A to 112N can include a media controller (e.g., media controller 113A and media controller 113N) to manage the memory cells of the memory component (e.g., to perform one or more memory management operations), to communicate with the memory sub-system controller 115, and to execute memory requests (e.g., read or write) received from the memory sub-system controller 115.

The memory sub-system controller 115 can include a media operations manager 122. The media operations manager 122 can perform selective extrinsic defect scan operations (e.g., RDCL scan operations) on a WL, WLG, component, memory die, and/or sub-block basis and based on a defect or reliability map associated with a memory sub-system. The media operations manager 122 can, during a BOL period of the memory sub-system, perform an aggressive extrinsic defect scan operation on mandatory (e.g., predetermined) portions (e.g., WL, WLG, memory dies, and so forth) of a set of memory components. The media operations manager 122 can use a result of the aggressive extrinsic defect scan operation to build or generate a table that identifies a subset of the mandatory portions that have a reliability value that fails to satisfy a reliability criterion (e.g., are associated with a RBER that is greater than an adjusted predetermined RBER). Then, during an EOL period of the memory sub-system 110, the media operations manager 122 can restrict performing the extrinsic defect scan operation to only those portions that are identified in the table. This ensures that performance of the memory system remains optimal, such as by restricting the number of portions for which an extrinsic defect scan operation is performed to only those portions known to be defective or that have poor reliability. This improves the overall efficiency of operating the memory sub-system 110.

In some examples, the media operations manager 122 can comprise logic (e.g., a set of transitory or non-transitory machine instructions, such as firmware) or one or more components that causes the media operations manager 122 to perform operations described herein. The media operations manager 122 can comprise a tangible or non-tangible unit capable of performing operations described herein. Further details with regards to the operations of the media operations manager 122 are described below.

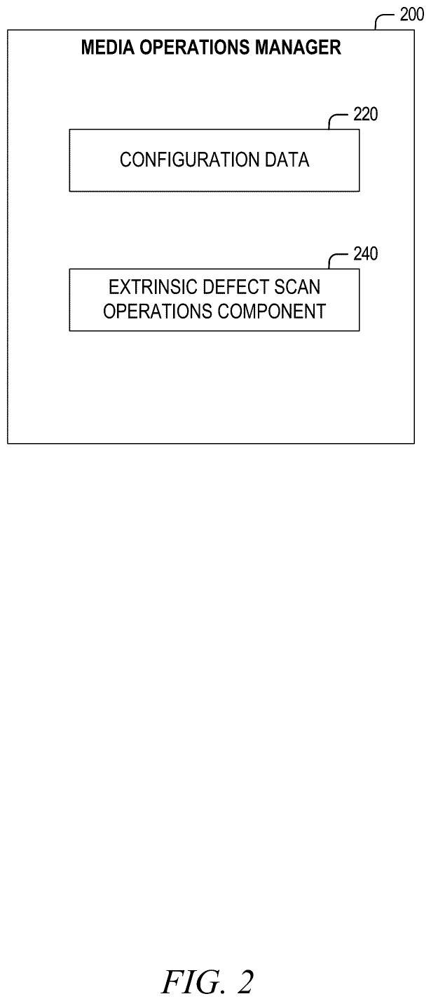

FIG. 2 is a block diagram of an example media operations manager 200 (corresponding to media operations manager 122 of FIG. 1), in accordance with some examples. As illustrated, the media operations manager 200 includes configuration data 220 and an extrinsic defect scan operation component 240. For some cases, the media operations manager 200 can differ in components or arrangement (e.g., less or more components) from what is illustrated in FIG. 2.

The configuration data 220 (e.g., configuration data component) accesses and/or stores configuration data associated with the memory components 112A to 112N of FIG. 1. In some examples, the configuration data 220 is programmed into the media operations manager 200. For example, the media operations manager 200 can communicate with the memory components 112A to 112N to obtain the configuration data and store the configuration data 220 locally on the media operations manager 200. In some examples, the media operations manager 200 communicates with the host system 120. The host system 120 receives input from an operator or user that specifies parameters including the list (or map) of different WLs, WLGs, bins, groups, blocks, block stripes, memory dies and/or sets of the memory components 112A to 112N that are defective (e.g., have a reliability value that fails to transgress a reliability threshold). The list or map can identify the mandatory portions to be included as part of a extrinsic defect scan operation. The media operations manager 200 receives configuration data from the host system 120 of FIG. 1 and stores the configuration data in the configuration data 220. The configuration data 220 can store a table or map that identifies different WL, WLGs, and/or SBs of the memory components 112A to 112N that are defective.

In some cases, the configuration data 220 can store reliability criteria that can be used to control whether an individual portion of the set of memory components 112A to 112N is included in a list of defective portions or portions having a low reliability value. Specifically, the configuration data 220 can store a predetermined RBER threshold that controls whether a memory block associated with one or more WLs is refreshed as a result of the extrinsic defect scan operations. In such cases, one or more portions (e.g., WLs or WLGs), which can be mandatory portions or subsets of the mandatory portions, are scanned as part of the extrinsic defect scan operations. An RBER value is computed or measured based on the result of performing the extrinsic defect scan operation. In response to the extrinsic defect scan operation component 240 determining that the RBER value associated with the one or more portions being scanned transgresses or exceeds the predetermined RBER threshold, the extrinsic defect scan operation component 240 can refresh the data stored in the one or more portions that were scanned.

In some examples, the extrinsic defect scan operation component 240 can perform a first type of extrinsic defect scan operation during a BOL period of the memory sub-system 110 and can perform a different second type of extrinsic defect scan operation during an EOL period of the memory sub-system 110. The BOL period can correspond to a first number of memory operations being performed on the memory sub-system 110 (e.g., a first number of write cycles, a first number of read cycles, a first number of PECs, and/or any combination thereof). The extrinsic defect scan operation component 240 can maintain a table that tracks the number of write cycles, number of read cycles, and/or number of PECs of the memory sub-system 110 as a whole or for individual portions of the set of memory components 112A to 112N. The extrinsic defect scan operation component 240 can determine whether the tracked number of write cycles, number of read cycles, and/or number of PECs is less than the first number of memory operations. If so, the external defect scan operation component 240 can determine that the memory sub-system 110 is in the BOL period and can perform the first type of extrinsic defect scan operations. In response to determining that the tracked number of write cycles, number of read cycles, and/or number of PECs transgresses or is greater than the first number of memory operations, the extrinsic defect scan operations component 240 can determine that the memory sub-system 110 is in the EOL period and can perform the second type of extrinsic defect scan operations.

In some examples, the first type of extrinsic defect scan operations (e.g., an aggressive RDCL scan operation) is triggered in response to the extrinsic defect scan operation component 240 determining that a specified portion or the memory sub-system 110 as a whole has been read a threshold number of times within a specified period of time. In such cases, the extrinsic defect scan operation component 240 can perform the first type of extrinsic defect scan operations by accessing a list of mandatory portions to be scanned and accessing the predetermined RBER threshold that controls refreshing the data. The extrinsic defect scan operation component 240 can modify the predetermined RBER threshold to increase sensitivity of the extrinsic defect scan operations, such as by reducing the RBER threshold value by a certain amount or percentage. The amount by which the RBER threshold value is reduced can be obtained from the configuration data 220 and/or from the host system 120.

The extrinsic defect scan operation component 240 can then measure the RBER value of each mandatory portion (e.g., each mandatory WL or WLG of each memory die). If the measured RBER value transgresses the modified or reduced RBER threshold, the extrinsic defect scan operation component 240 can add that mandatory portion to a table of a subset of the mandatory portions that are identified has having a reliability value that fails to satisfy a reliability criterion.

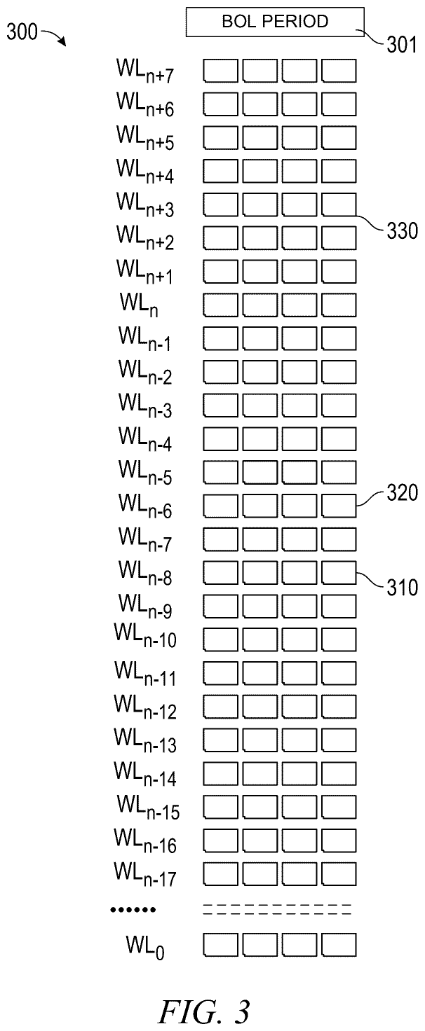

For example, as shown in the diagram 300 of FIG. 3, the extrinsic defect scan operation component 240 of FIG. 2 can scan WLs 310, 320, and 330 (e.g., mandatory WLs) during a BOL period 301. The diagram 300 (and diagram 400 discussed below) illustrate extrinsic defect scan operation, such as extrinsic RDCL scan operations due to die-to-die variations and/or WL-to-WL variations. The extrinsic defect scan operation component 240 can determine that the WL 310 is associated with a reliability value that fails to satisfy the reliability criterion in response to determining that the RBER of the data stored in the WL 310 transgresses the modified or reduced RBER threshold. In such cases, the extrinsic defect scan operation component 240 adds the WL 310 to a table that identifies portions having reliability values that fail to satisfy a reliability criterion. The extrinsic defect scan operation component 240 can determine that the RBER of the data stored in the WLs 320 and 330 fails to transgress the modified or reduced RBER threshold. In such cases, the extrinsic defect scan operation component 240 can determine whether the data stored in the WLs 320 and 330 transgresses the unmodified predetermined RBER threshold. If so, the extrinsic defect scan operation component 240 refreshes the data stored in association with the WLs 320 and 330. If not, the extrinsic defect scan operation component 240 refrains from performing further operations on the data stored in association with the WLs 320 and 330.

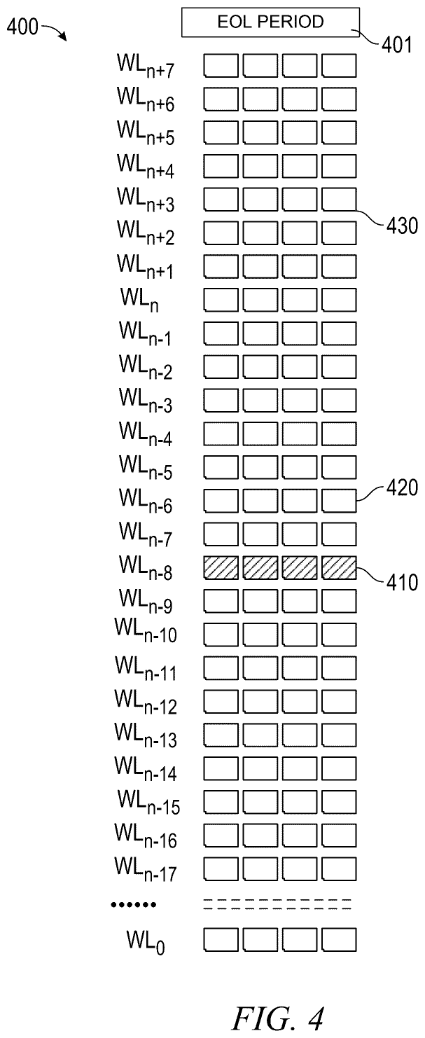

In some examples, the extrinsic defect scan operation component 240 can determine that the number of memory operations performed on the memory sub-system 110 transgresses a first number of memory operations. In such cases, the extrinsic defect scan operation component 240 can determine that the memory sub-system 110 is in the EOL period 401, shown in the diagram 400 of FIG. 4. In such cases, the extrinsic defect scan operation component 240 can perform a second type of extrinsic defect scan operation when a condition is met. For example, the extrinsic defect scan operation component 240 can determine that a specified portion or the memory sub-system 110 as a whole has been read the threshold number of times within the specified period of time. In such cases, the extrinsic defect scan operation component 240 can perform the second type of extrinsic defect scan operation.

In such cases, the extrinsic defect scan operation component 240 can access the table or map that lists the defective portions or portions of the memory sub-system 110 that have a reliability value that fails to satisfy the reliability criterion. These portions were identified as a result of performing the aggressive RDCL operations (e.g., the first type of extrinsic defect scan operations in the BOL period 301). The extrinsic defect scan operation component 240 can determine that the WL 410 is included in the table or map and that other WLs 420 and 430 (which are included in the mandatory portions to be scanned in the extrinsic defect scan operations) are excluded or not included in the table or map. In such cases, the extrinsic defect scan operation component 240 can only perform the extrinsic defect scan operations on the portions listed in the table or map and not on all the mandatory portions specified in the configuration data 220.

For example, the extrinsic defect scan operation component 240 can scan or read charges stored in the WL 410 and measure the RBER value of the data stored in the WL 410. If the measured RBER value transgresses the predetermined RBER threshold (e.g., the unmodified RBER threshold), the extrinsic defect scan operation component 240 can refresh the data stored in association with the WL 410. The extrinsic defect scan operation component 240 can skip scanning or reading charges stored in the other WLs 420 and 430 during the EOL period 401 and when the extrinsic defect scan operations are performed. This reduces the amount of time it takes to perform the extrinsic defect scan operations, which improves the overall efficiency of operating the memory sub-system 110.

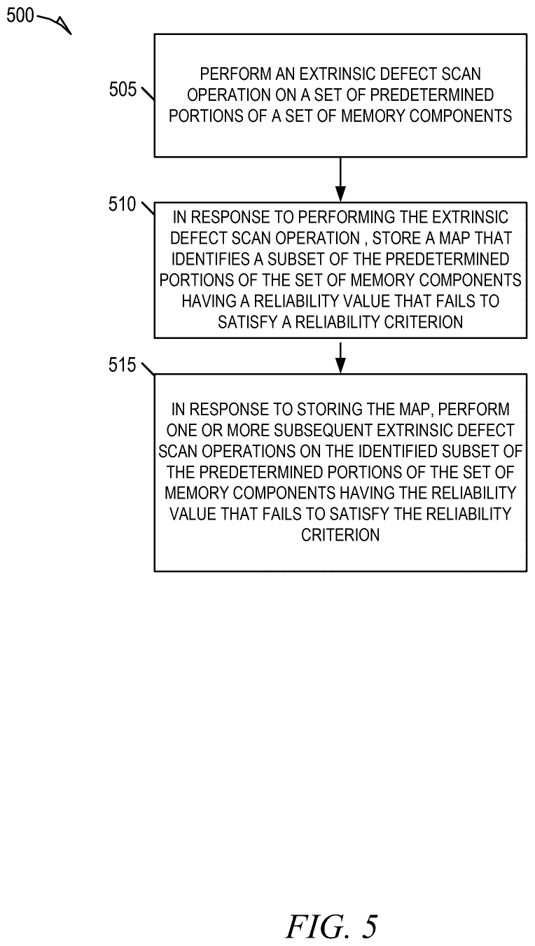

FIG. 5 is a flow diagram of an example method 500 (or process) to selectively perform an extrinsic defect scan operation on memory components, in accordance with some examples. The method 500 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 500 is performed by the media operations manager 122 of FIG. 1. Although the processes are shown in a particular sequence or order, unless otherwise specified, the order of the processes can be modified. Thus, the illustrated examples should be understood only as examples, and the illustrated processes can be performed in a different order, and some processes can be performed in parallel. Additionally, one or more processes can be omitted in various examples. Thus, not all processes are required in every examples. Other process flows are possible.

Referring now to FIG. 5, the method (or process) 500 begins at operation 505, with a media operations manager 122 of FIG. 1 of a memory sub-system (e.g., memory sub-system 110 of FIG. 1) performing an extrinsic defect scan operation on a set of predetermined portions of a set of memory components. Then, at operation 510, the media operations manager 122 of the memory sub-system, in response to performing the extrinsic defect scan operation, stores a map that identifies a subset of the predetermined portions of the set of memory components having a reliability value that fails to satisfy a reliability criterion. Thereafter, at operation 515, the media operations manager 122, in response to storing the map, performs one or more subsequent extrinsic defect scan operations on the identified subset of the predetermined portions of the set of memory components having the reliability value that fails to satisfy the reliability criterion.

In view of the disclosure above, various examples are set forth below. It should be noted that one or more features of an example, taken in isolation or combination, should be considered within the disclosure of this application.

Example 1: A system comprising: a set of memory components of a memory sub-system; and at least one processing device operatively coupled to the set of memory components, the at least one processing device being configured to perform operations comprising: performing an extrinsic defect scan operation on a set of predetermined portions of the set of memory components; in response to performing the extrinsic defect scan operation, storing data (e.g., a map) that identifies a subset of the set of predetermined portions of the set of memory components having a reliability value that fails to satisfy a reliability criterion; and in response to storing the data (e.g., the map), performing one or more subsequent extrinsic defect scan operations on the identified subset of the set of predetermined portions of the set of memory components having the reliability value that fails to satisfy the reliability criterion.

Example 2. The system of Example 1, wherein the extrinsic defect scan operation comprises a RDCL scan operation, and wherein the memory sub-system comprises a three-dimensional (3D) NAND memory the memory sub-system comprises a three-dimensional (3D) NAND memory.

Example 3. The system of any one of Examples 1-2, the operations comprising: determining that a program erase count (PEC) associated with the set of memory components corresponds to a beginning of life (BOL) period; and in response to determining that the PEC associated with the set of memory components corresponds to the BOL period, performing the extrinsic defect scan operation on the set of predetermined portions of the set of memory components.

Example 4. The system of Example 3, the operations comprising: obtaining a predetermined reliability threshold associated with the extrinsic defect scan operation; and during, the BOL period, modifying the predetermined reliability threshold to increase sensitivity of the reliability criterion.

Example 5. The system of Example 4, wherein the predetermined reliability threshold represents a predetermined read bit error rate (RBER) value, and wherein the reliability value comprises a RBER of the subset of the set of predetermined portions of the set of memory components, the operations comprising: reducing the predetermined RBER value of the predetermined reliability threshold to increase sensitivity of the reliability criterion.

Example 6. The system of Example 5, the operations comprising: measuring the RBER value of each of the set of predetermined portions of the set of memory components responsive to performing the extrinsic defect scan operation during the BOL period; determining that the RBER value of an individual portion of the set of predetermined portions transgresses a reduced predetermined RBER value; and in response to determining that the RBER value of the individual portion of the set of predetermined portions transgresses the reduced predetermined RBER value, adding the individual portion to the map of the subset that identifies the subset of the set of predetermined portions of the set of memory components having the reliability value that fails to satisfy the reliability criterion.

Example 7. The system of any one of Examples 5-6, the operations comprising: triggering refresh of data stored in one or more portions of the subset of the set of predetermined portions of the set of memory components in response to determining that RBER values associated with the one or more portions of the subset of the set of predetermined portions transgress the predetermined RBER value.

Example 8. The system of any one of Examples 3-7, the operations comprising: continuing to perform the extrinsic defect scan operation on the set of predetermined portions of the set of memory components until the PEC associated with the set of memory components corresponds to an end of life (EOL) period.

Example 9. The system of Example 8, the operations comprising: determining that the PEC associated with the set of memory components corresponds to the EOL period; and in response to determining that the PEC associated with the set of memory components corresponds to the EOL period, performing the one or more subsequent extrinsic defect scan operations on the identified subset of the set of predetermined portions of the set of memory components having the reliability value that fails to satisfy the reliability criterion.

Example 10. The system of Example 9, wherein the identified subset excludes one or more portions that are in the set of predetermined portions of the set of memory components.

Example 11. The system of any one of Examples 9-10, wherein the extrinsic defect scan operation is performed on a first number of portions of the set of memory components during the BOL period, and wherein the one or more subsequent extrinsic defect scan operations are performed on a second number of portions of the set of memory components during the EOL period, and wherein the second number of portions is smaller than the first number of portions.

Example 12. The system of any one of Examples 1-11, wherein the set of portions comprises at least one of a set of word lines (WLs), WL groups (WLGs), or set of memory dies.

Example 13. The system of any one of Examples 1-12, wherein the extrinsic defect scan operation and the one or more subsequent extrinsic defect scan operations are triggered periodically.

Example 14. The system of any one of Examples 1-13, wherein the extrinsic defect scan operation and the one or more subsequent extrinsic defect scan operations are triggered in response to determining that a number of read operations performed on the memory sub-system within a predetermined interval transgresses a threshold value.

Methods and computer-readable storage medium with instructions for performing any one of the above Examples.

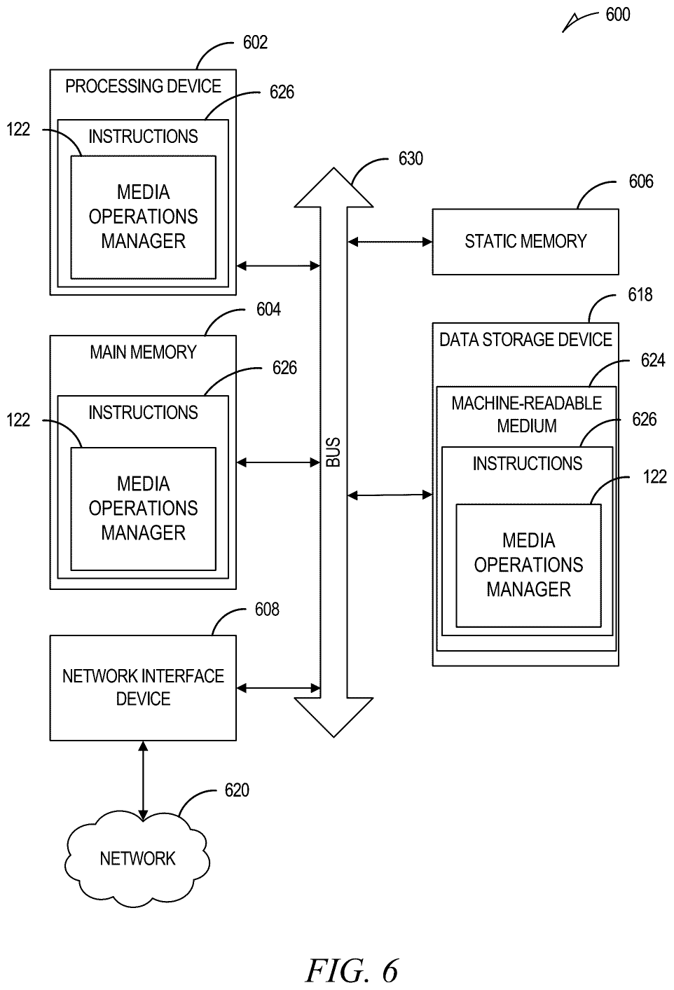

FIG. 6 illustrates an example machine in the form of a computer system 600 within which a set of instructions can be executed for causing the machine to perform any one or more of the methodologies discussed herein. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the media operations manager 122 of FIG. 1). In alternative embodiments, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a network switch, a network bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage device 618, which communicate with each other via a bus 630.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), a network processor, or the like. The processing device 602 is configured to execute instructions 626 for performing the operations and steps discussed herein. The computer system 600 can further include a network interface device 608 to communicate over a network 620.

The data storage device 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage device 618, and/or main memory 604 can correspond to the memory sub-system 110 of FIG. 1.

In one embodiment, the instructions 626 implement functionality corresponding to the media operations manager 122 of FIG. 1. While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system's memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks; read-only memories (ROMs); random access memories (RAMs); erasable programmable read-only memories (EPROMs); EEPROMs; magnetic or optical cards; or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description above. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine-readable (e.g., computer-readable) storage medium such as a read-only memory (ROM), random access memory (RAM), magnetic disk storage media, optical storage media, flash memory components, and so forth.

In the foregoing specification, various examples of the disclosure have been described. It will be evident that various modifications can be made thereto without departing from the broader scope of the disclosure as set forth in the following claims. The specification and drawings are, accordingly, to be regarded in an illustrative sense rather than a restrictive sense.

What is claimed is:

1. A system comprising:
a set of memory components of a memory sub-system; and
at least one processing device operatively coupled to the set of memory components, the at least one processing device being configured to perform operations comprising:
performing an extrinsic defect scan operation on a set of predetermined portions of the set of memory components;
in response to performing the extrinsic defect scan operation, storing data that identifies a subset of the set of predetermined portions of the set of memory components having a reliability value that fails to satisfy a reliability criterion; and
in response to storing the data, performing one or more subsequent extrinsic defect scan operations on the identified subset of the set of predetermined portions of the set of memory components having the reliability value that fails to satisfy the reliability criterion.

2. The system of claim 1, wherein the extrinsic defect scan operation comprises an read disturb induced charge loss (RDCL) scan operation, and wherein the memory sub-system comprises a three-dimensional (3D) NAND memory.

3. The system of claim 1, the operations comprising:
determining that a program erase count (PEC) associated with the set of memory components corresponds to a beginning of life (BOL) period; and
in response to determining that the PEC associated with the set of memory components corresponds to the BOL period, performing the extrinsic defect scan operation on the set of predetermined portions of the set of memory components.

4. The system of claim 3, the operations comprising:
obtaining a predetermined reliability threshold associated with the extrinsic defect scan operation; and
during, the BOL period, modifying the predetermined reliability threshold to increase sensitivity of the reliability criterion.

5. The system of claim 4, wherein the predetermined reliability threshold represents a predetermined read bit error rate (RBER) value, and wherein the reliability value comprises a RBER of the subset of the set of predetermined portions of the set of memory components, the operations comprising:
reducing the predetermined RBER value of the predetermined reliability threshold to increase sensitivity of the reliability criterion.

6. The system of claim 5, the operations comprising:
measuring the RBER value of each of the set of predetermined portions of the set of memory components responsive to performing the extrinsic defect scan operation during the BOL period;
determining that the RBER value of an individual portion of the set of predetermined portions transgresses a reduced predetermined RBER value; and
in response to determining that the RBER value of the individual portion of the set of predetermined portions transgresses the reduced predetermined RBER value, adding the individual portion to the data that identifies the subset of the set of predetermined portions of the set of memory components having the reliability value that fails to satisfy the reliability criterion.

7. The system of claim 5, the operations comprising:
triggering refresh of data stored in one or more portions of the subset of the set of predetermined portions of the set of memory components in response to determining that RBER values associated with the one or more portions of the subset of the set of predetermined portions transgress the predetermined RBER value.

8. The system of claim 3, the operations comprising:
continuing to perform the extrinsic defect scan operation on the set of predetermined portions of the set of memory components until the PEC associated with the set of memory components corresponds to an end of life (EOL) period.

9. The system of claim 8, the operations comprising:
determining that the PEC associated with the set of memory components corresponds to the EOL period; and
in response to determining that the PEC associated with the set of memory components corresponds to the EOL period, performing the one or more subsequent extrinsic defect scan operations on the identified subset of the set of predetermined portions of the set of memory components having the reliability value that fails to satisfy the reliability criterion.

10. The system of claim 9, wherein the identified subset excludes one or more portions that are in the set of predetermined portions of the set of memory components.

11. The system of claim 9, wherein the extrinsic defect scan operation is performed on a first number of portions of the set of memory components during the BOL period, and wherein the one or more subsequent extrinsic defect scan operations are performed on a second number of portions of the set of memory components during the EOL period, and wherein the second number of portions is smaller than the first number of portions.

12. The system of claim 1, wherein the set of portions comprises at least one of a set of word lines (WLs), WL groups (WLGs), or set of memory dies.

13. The system of claim 1, wherein the extrinsic defect scan operation and the one or more subsequent extrinsic defect scan operations are triggered periodically.

14. The system of claim 1, wherein the extrinsic defect scan operation and the one or more subsequent extrinsic defect scan operations are triggered in response to determining that a number of read operations performed on the memory sub-system within a predetermined interval transgresses a threshold value.

15. A method comprising:
performing an extrinsic defect scan operation on a set of predetermined portions of a set of memory components;
in response to performing the extrinsic defect scan operation, storing data that identifies a subset of the set of predetermined portions of the set of memory components having a reliability value that fails to satisfy a reliability criterion; and
in response to storing the data, performing one or more subsequent extrinsic defect scan operations on the identified subset of the set of predetermined portions of the set of memory components having the reliability value that fails to satisfy the reliability criterion.

16. The method of claim 15, wherein the set of memory components is part of a three-dimensional (3D) NAND memory.

17. The method of claim 15, comprising:
determining that a program erase count (PEC) associated with the set of memory components corresponds to a beginning of life (BOL) period; and
in response to determining that the PEC associated with the set of memory components corresponds to the BOL period, performing the extrinsic defect scan operation on the set of predetermined portions of the set of memory components.

18. The method of claim 17, comprising:
obtaining a predetermined reliability threshold associated with the extrinsic defect scan operation; and
during the BOL period, modifying the predetermined reliability threshold to increase sensitivity of the reliability criterion.

19. The method of claim 18, wherein the predetermined reliability threshold represents a predetermined read bit error rate (RBER) value, and wherein the reliability value comprises a RBER of the subset of the set of predetermined portions of the set of memory components, comprising:
reducing the predetermined RBER value of the predetermined reliability threshold to increase sensitivity of the reliability criterion.

20. A non-transitory computer-readable storage medium comprising instructions that, when executed by at least one processing device, cause the at least one processing device to perform operations comprising:
performing an extrinsic defect scan operation on a set of predetermined portions of a set of memory components;
in response to performing the extrinsic defect scan operation, storing data that identifies a subset of the set of predetermined portions of the set of memory components having a reliability value that fails to satisfy a reliability criterion; and
in response to storing the data, performing one or more subsequent extrinsic defect scan operations on the identified subset of the set of predetermined portions of the set of memory components having the reliability value that fails to satisfy the reliability criterion.
